(19) United States
(12) Patent Application Publication
(10) Pub. No.: US 2025/0331172 A1
(43) Pub. Date: Oct. 23, 2025

(54) SEMICONDUCTOR DEVICE

(71) Applicant: SAMSUNG ELECTRONICS CO., LTD., Suwon-si (KR)

(72) Inventors: SeungWan YOO, Suwon-si (KR); Dohyung KIM, Suwon-si (KR); HYUNG-SEOK HONG, Suwon-si (KR); SeungHyun KIM, Suwon-si (KR); Taeyoung KIM, Suwon-si (KR); Jaewon JUNG, Suwon-si (KR)

(73) Assignee: SAMSUNG ELECTRONICS CO., LTD., Suwon-si (KR)

(21) Appl. No.: 18/972,214

(22) Filed: Dec. 6, 2024

(30) Foreign Application Priority Data
Apr. 18, 2024 (KR) 10-2024-0052120

(51) Int. Cl. H10B 12/00; H10B 61/00; H10B 63/00; H10B 63/10

(52) U.S. Cl. CPC H10B 12/485; H10B 12/482; H10B 61/22; H10B 63/10; H10B 63/30

(57) ABSTRACT

A semiconductor device is provided. The semiconductor device includes: a substrate with an active pattern; a bit line crossing the active pattern on the substrate; a bit line contact provided between the bit line and the active pattern; a first silicide layer provided between the bit line contact and the bit line; and a second silicide layer provided between the first silicide layer and the bit line. Each of the first silicide layer and the second silicide layer includes a metal element, silicon (Si) and nitrogen (N). The first silicide layer has a first nitrogen concentration, and the second silicide layer has a second nitrogen concentration that is greater than the first nitrogen concentration.

### CROSS-REFERENCE TO RELATED APPLICATION

This application claims priority under 35 U.S.C. § 119 to Korean Patent Application No. 10-2024-0052120, filed on Apr. 18, 2024, in the Korean Intellectual Property Office, the disclosure of which is incorporated by reference herein in its entirety.

### BACKGROUND

The present disclosure relates to a semiconductor device, and more particularly, relates to a semiconductor device including a silicide layer.

A semiconductor device includes an integrated circuit including a metal-oxide-semiconductor field-effect transistor (MOSFET). As sizes and design rules of semiconductor devices are gradually reduced, the MOSFETs are increasingly rapidly downscaled. The downscaling of the MOSFETs may cause a short channel effect, thereby degrading operating characteristics of the semiconductor devices. Thus, research has been conducted into various methods for forming semiconductor devices having better performance by overcoming limitations due to an increase in the integration density of the semiconductor devices.

### SUMMARY

One or more example embodiments provide a semiconductor device with improved reliability and electrical characteristics.

According to an aspect of an example embodiment, a semiconductor device includes: a substrate including an active pattern; a bit line crossing the active pattern on the substrate; a bit line contact provided between the bit line and the active pattern; a first silicide layer provided between the bit line contact and the bit line; and a second silicide layer provided between the first silicide layer and the bit line. Each of the first silicide layer and the second silicide layer includes a metal element, silicon (Si) and nitrogen (N). The first silicide layer has a first nitrogen concentration, and the second silicide layer has a second nitrogen concentration that is greater than the first nitrogen concentration.

According to another aspect of an example embodiment, a semiconductor device includes: a substrate with an active pattern; a bit line crossing the active pattern on the substrate; a bit line contact provided between the bit line and the active pattern; and a silicide layer provided between the bit line contact and the bit line, the silicide layer including a first region adjacent to the bit line contact and a second region adjacent to the bit line. The silicide layer includes a metal element, silicon (Si) and nitrogen (N). A nitrogen concentration of the silicide layer increases from along a direction perpendicular to an upper surface of the substrate.

According to another aspect of an example embodiment, a semiconductor device includes: a device isolation pattern defining active patterns on a substrate; word lines crossing the active patterns on the substrate; bit lines crossing the active patterns and intersecting the word lines; a bit line contact provided between a central portion of an active pattern of the active patterns and a bit line of the bit lines; a first silicide layer provided between the bit line contact and the bit line; a second silicide layer provided between the first silicide layer and the bit line; a storage node contact provided on the active patterns on both sides of the bit line; a landing pad on the storage node contact; and a data storage pattern on the landing pad. Each of the first silicide layer and the second silicide layer includes a metal element, silicon (Si) and nitrogen (N). The first silicide layer has a first nitrogen concentration and the second silicide layer has a second nitrogen concentration that is greater than the first nitrogen concentration.

### BRIEF DESCRIPTION OF DRAWINGS

The above and other aspects and features will be more apparent from the following description of example embodiments, taken in conjunction with the accompanying drawings, in which:

FIG. 1A is a plan view of a semiconductor device according to example embodiments;

FIG. 1B is a view illustrating a semiconductor device according to example embodiments, and is an enlarged view corresponding to region ‘M’ of FIG. 1A;

FIG. 2 is a view illustrating a semiconductor device according to example embodiments, and is an enlarged view corresponding to region ‘M1’ in FIG. 1B;

FIG. 3 is a view illustrating a semiconductor device according to example embodiments, and is a cross-sectional view corresponding to line A-A′ in FIG. 2;

FIG. 4 is a view illustrating a semiconductor device according to example embodiments, and is a cross-sectional view corresponding to line B-B′ in FIG. 2;

FIGS. 5 and 6 are views illustrating semiconductor devices according to example embodiments, and are enlarged views corresponding to region ‘M2’ in FIG. 4;

FIG. 7 is a view illustrating a semiconductor device according to example embodiments, and is a cross-sectional view corresponding to line A-A′ of FIG. 2;

FIG. 8 is a view illustrating a semiconductor device according to example embodiments, and is a cross-sectional view corresponding to line B-B′ in FIG. 2;

FIG. 9 is a view illustrating a semiconductor device according to example embodiments, and is an enlarged view corresponding to region ‘M3’ in FIG. 8;

FIG. 10 is a view illustrating a semiconductor device according to example embodiments, and is a cross-sectional view corresponding to line A-A′ in FIG. 2;

FIG. 11 is a view illustrating a semiconductor device according to example embodiments, and is a cross-sectional view corresponding to line B-B′ in FIG. 2;

FIG. 12 is a view illustrating a semiconductor device according to example embodiments, and is an enlarged view corresponding to region ‘M4’ in FIG. 11;

FIG. 13 is a view illustrating a semiconductor device according to example embodiments, and is a cross-sectional view corresponding to line A-A′ in FIG. 2;

FIG. 14 is a view illustrating a semiconductor device according to example embodiments, and is a cross-sectional view corresponding to line B-B′ in FIG. 2; and

FIG. 15 is a view illustrating a semiconductor device according to example embodiments, and is an enlarged view corresponding to region ‘M5’ in FIG. 14.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one from among,” and “at least one of,” when preceding a list of elements, modify the entire list of elements and do not modify the individual elements of the list. For example, the expression, “at least one from among a, b, and c,” should be understood as including only a, only b, only c, both a and b, both a and c, both b and c, or all of a, b, and c. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

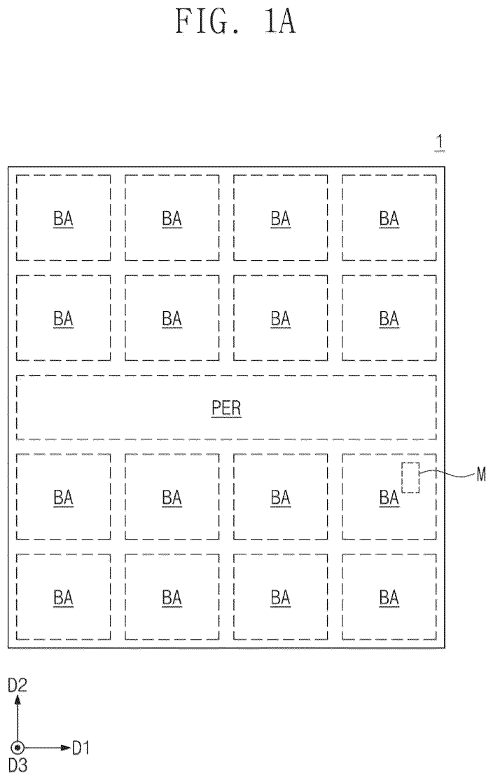

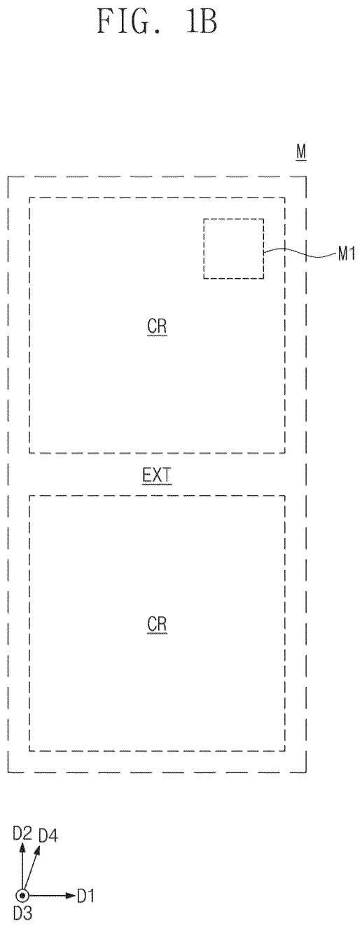

FIG. 1A is a plan view of a semiconductor device according to example embodiments. FIG. 1B is a view illustrating a semiconductor device according to example embodiments, and is an enlarged view corresponding to region ‘M’ of FIG. 1A.

Referring to FIGS. 1A and 1B, a semiconductor device 1 may include a plurality of banks BA and a peripheral region PER. The peripheral region PER may be disposed between the banks BA. Peripheral circuits for input/output of data or commands, or input of power/ground may be disposed in the peripheral region PER.

Each of the banks BA may include cell block regions CR and an extension region EXT between the cell block regions CR. Each of the cell block regions CR may include a memory cell array, a sense amplifier region, and a sub-word line driver region. Sense amplifiers (i.e., sense amplifier circuits) may be disposed in the sense amplifier region. Sub-word line drivers (i.e., sub-word line driver circuits) may be disposed in the sub-word line driver region.

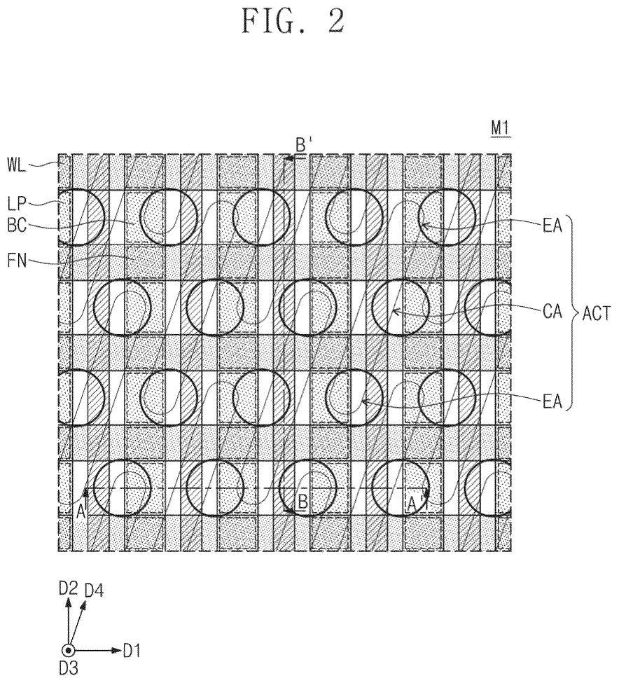

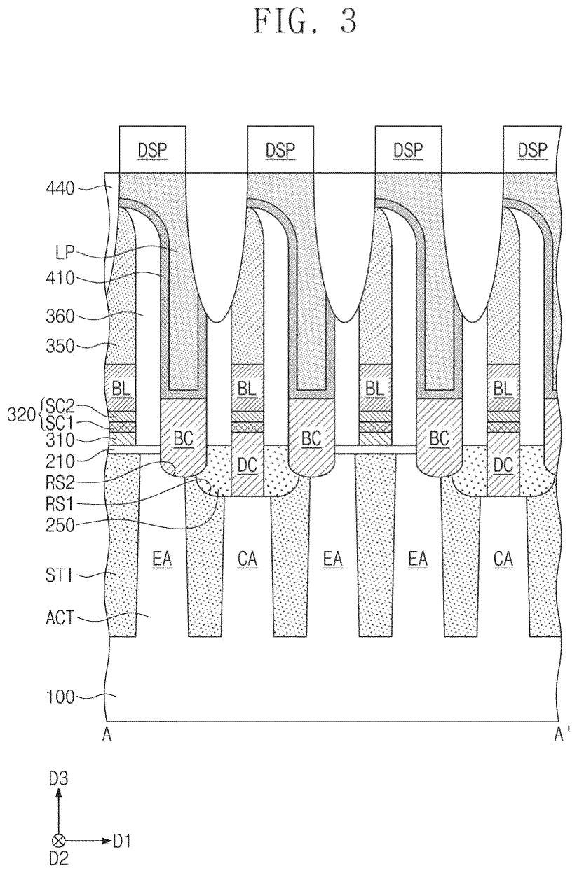

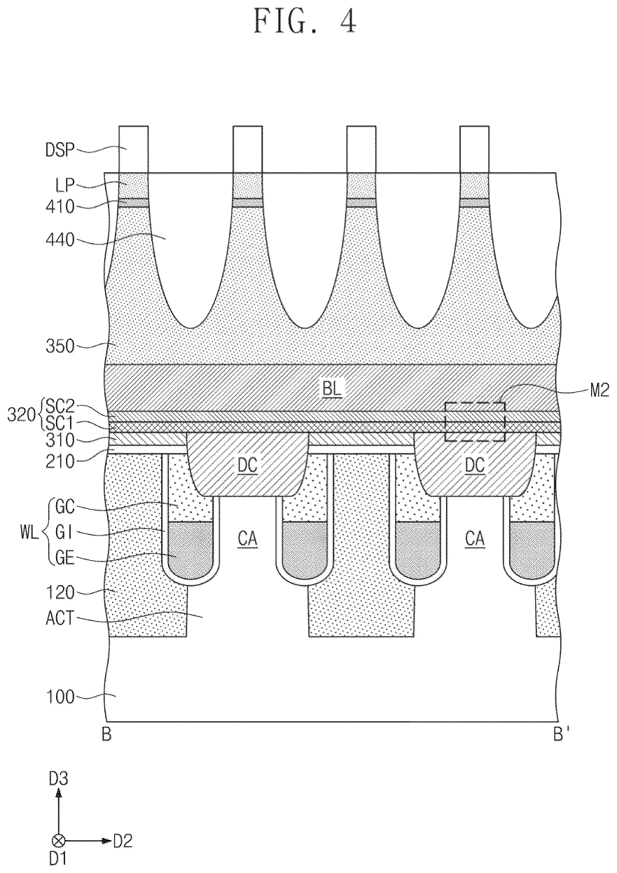

FIG. 2 is a view illustrating a semiconductor device according to example embodiments, and is an enlarged view corresponding to region ‘M1’ in FIG. 1B. FIG. 3 is a view illustrating a semiconductor device according to example embodiments, and is a cross-sectional view corresponding to line A-A′ in FIG. 2. FIG. 4 is a view illustrating a semiconductor device according to example embodiments, and is a cross-sectional view corresponding to line B-B′ in FIG. 2.

Referring to FIGS. 2 to 4, a device isolation pattern STI may be provided on a substrate 100. The device isolation pattern STI may define active patterns ACT on the substrate 100. Each of the active patterns ACT may protrude in a third direction D3 perpendicular to the substrate 100. As an example, the device isolation pattern STI may be disposed in the substrate 100, and the active patterns ACT may be portions of the substrate 100 surrounded by the device isolation pattern STI. For convenience of explanation, unless otherwise specified, in this example embodiment, the substrate 100 is defined to refer to other portions of the substrate 100 excluding the active patterns ACT.

The active patterns ACT may be disposed to be spaced apart from each other in a first direction D1 and a second direction D2. Each of the active patterns ACT may have an island shape separated from other active patterns ACT and may have a bar shape elongated in a fourth direction D4. The fourth direction D4 may be parallel to a lower surface of the substrate 100 and may intersect the first and second directions D1 and D2.

Each of the active patterns ACT may include a pair of edge portions EA and a center portion CA. A pair of edge portions EA may be both ends of the active pattern ACT in the fourth direction D4, respectively. The center portion CA may be a portion of an active pattern ACT interposed between the pair of edge portions EA, and in detail, may be a portion of the active pattern ACT interposed between a pair of word lines WL, which will be described later. Each of the pair of edge portions EA and the center portion CA may include an impurity region doped with an impurity (e.g., an n-type or p-type impurity).

The device isolation pattern STI may include an insulating material. As an example, the device isolation pattern STI may include at least one of silicon oxide and silicon nitride. As an example, the device isolation pattern STI may be a single layer formed of any of the above materials or a composite layer formed of two or more materials.

The word line WL may cross the active patterns ACT. As an example, the word line WL may cross the active patterns ACT and the device isolation pattern STI in the first direction D1. A plurality of word lines WL may be provided. The plurality of word lines WL may be spaced apart from each other in the second direction D2. For example, a pair of word lines WL adjacent to each other in the second direction D2 may cross one active pattern ACT.

For example, each of the word lines WL may include a gate electrode GE, a gate insulating pattern GI, and a gate capping pattern GC. The gate electrode GE may cross the active patterns ACT and the device isolation pattern STI in the first direction D1. The gate insulating pattern GI may be interposed between the gate electrode GE and the active patterns ACT. The gate capping pattern GC may cover an upper surface of the gate electrode GE.

A buffer pattern 210 may be disposed on the substrate 100. The buffer pattern 210 may cover the active patterns ACT, the device isolation pattern STI, and the word lines WL. As an example, the buffer pattern 210 may include at least one of silicon oxide, silicon nitride, and silicon oxynitride. The buffer pattern 210 may be a single layer formed of a single material or a composite layer containing two or more materials.

A bit line contact DC may be provided on each of the active patterns ACT, and may be provided in plural. Each of the bit line contacts DC may be connected to a corresponding one of the center portions CA of the active patterns ACT. The bit line contacts DC may be spaced apart from each other in the first and second directions D1 and D2. The bit line contacts DC may be interposed between the active patterns ACT and bit lines BL, which will be described later. The bit line contacts DC may connect the corresponding bit line BL among the bit lines BL and the center portion CA of the corresponding active pattern ACT. As an example, the bit line contact DC may include polysilicon doped with impurities.

The bit line contacts DC may be disposed in first recess regions RS1, respectively. The first recess regions RS1 may be provided on the active patterns ACT and on the device isolation pattern STI adjacent to the active patterns ACT. The first recess regions RS1 may be spaced apart from each other in the first and second directions D1 and D2.

A buried insulating pattern 250 may fill each of the first recess regions RS1 around the bit line contacts DC. The buried insulating pattern 250 may fill an interior of the first recess region RS1. As an example, the buried insulating pattern 250 may cover at least a portion of an inner surface of the first recess region RS1 and a side surface of the bit line contact DC (e.g., at least a portion of side surface of the bit line contact DC in the first recess region RS1). The buried insulating pattern 250 may include at least one of silicon oxide, silicon nitride, or a combination thereof. The buried insulating pattern 250 may be a single layer formed of a single material or a composite layer containing two or more materials.

A bit line BL may be provided on the bit line contact DC. The bit line BL may be disposed on a row of bit line contacts DC arranged in the second direction D2. A plurality of bit lines BL may be provided. The bit lines BL may be spaced apart from each other in the first direction D1. The bit line BL may include a metal element. As an example, the metal element may be Ti, Mo, W, Cu, Al, Ta, Ru, Ir, Co, Pt, Au, Ag, etc.

A polysilicon pattern 310 may be interposed between the bit line BL and the buffer pattern 210. An upper surface of the polysilicon pattern 310 may be positioned at substantially the same height as an upper surface of the bit line contact DC. The polysilicon pattern 310 may include polysilicon doped with impurities.

An ohmic pattern 320 may be interposed between the bit line BL and the bit line contact DC, and between the bit line BL and the polysilicon pattern 310. The ohmic pattern 320 may include a first silicide layer SC1 and a second silicide layer SC2. The first silicide layer SC1 and the second silicide layer SC2 may vertically overlap the corresponding polysilicon pattern 310 or bit line contact DC. The first silicide layer SC1 may be interposed between the second silicide layer SC2 and the bit line contact DC, and between the second silicide layer SC2 and the polysilicon pattern 310. The second silicide layer SC2 may be interposed between the first silicide layer SC1 and the bit line BL. Each of the first silicide layer SC1 and the second silicide layer SC2 may include the metal element (e.g., Ti, Mo, W, Cu, Al, Ta, Ru, Ir, Co, Pt, Au, Ag, etc.), silicon (Si), and nitrogen (N).

A bit line capping pattern 350 may be provided on the bit line BL. As an example, each of the bit line capping patterns 350 may be provided on an upper surface of the corresponding bit line BL. As an example, the bit line capping patterns 350 may each extend in the second direction D2 along the corresponding bit line BL and may be spaced apart from each other in the first direction D1. Each of the bit line capping patterns 350 may vertically overlap the corresponding bit line BL. The bit line capping pattern 350 may be composed of a single layer or multiple layers. As an example, the bit line capping pattern 350 may include a first capping pattern, a second capping pattern, and a third capping pattern that are sequentially stacked. As an example, each of the first to third capping patterns may include silicon nitride. As another example, the bit line capping pattern may further include additional capping patterns such as fourth and fifth capping patterns.

Bit line spacers 360 may be provided on side surfaces of the bit lines BL and side surfaces of the bit line capping patterns 350. Each bit line spacer 360 may cover a side surface of the bit line BL and a side surface of the bit line capping pattern 350. The bit line spacers 360 may extend in the second direction D2 on the side surfaces of the bit line BL.

Each of the bit line spacers 360 may include a plurality of sub-spacers. As an example, each of the bit line spacers 360 may include three or more layers of sub-spacers sequentially provided on the side surface of the bit line BL. For example, each of the sub-spacers may independently include at least one of silicon nitride, silicon oxide, and silicon oxynitride. As another example, at least some of the sub-spacers may include a type of air gap that separates other sub-spacers from each other.

A storage node contact BC may be provided between neighboring bit lines BL. A plurality of storage node contacts BC may be provided, and the storage node contacts BC may be spaced apart from each other in the first and second directions D1 and D2. The storage node contact BC may fill a second recess region RS2 on the edge portion EA of the active pattern ACT. The storage node contact BC may be electrically connected to the edge portion EA. The storage node contact BC may include a conductive material. As an example, the storage node contact BC may include at least one of polysilicon with impurities and a metal element (e.g., Ti, Mo, W, Cu, Al, Ta, Ru, Ir, Co, Pt, Au, Ag, etc.).

Fence patterns FN may separate the storage node contacts BC from each other in the second direction D2 on the word lines WL. As an example, the fence patterns FN may be spaced apart from each other in the second direction D2 with the storage node contacts BC interposed therebetween. As an example, the fence patterns FN may include silicon nitride.

A barrier pattern 410 may conformally cover the storage node contact BC and the bit line spacer 360. The barrier pattern 410 may include a conductive metal nitride. The metal element of the metal nitride may be Ti, Mo, W, Cu, Al, Ta, Ru, Ir, Co, Pt, Au, Ag, etc. A metal silicide layer may be further interposed between the barrier pattern 410 and the storage node contact BC.

A landing pad LP may be provided on the storage node contact BC. A plurality of landing pads LP may be provided, and the landing pads LP may be spaced apart from each other in the first and second directions D1 and D2. The landing pad LP may be connected to a corresponding storage node contact BC. The landing pad LP may cover an upper surface of the bit line capping pattern 350. For example, a lower portion of the landing pad LP may vertically overlap the storage node contact BC, and an upper portion of the landing pad LP may be shifted from the lower portion thereof in the second direction D2 or the opposite direction. The landing pad LP may include a metal element (e.g., Ti, Mo, W, Cu, Al, Ta, Ru, Ir, Co, Pt, Au, Ag, etc.).

A filling pattern 440 may surround the landing pad LP. The filling pattern 440 may be interposed between adjacent landing pads LP. When viewed in a plan view, the filling pattern 440 may have a mesh shape including holes penetrated by the landing pads LP. As an example, the filling pattern 440 may include at least one of silicon nitride, silicon oxide, and silicon oxynitride. As another example, the filling pattern 440 may include an empty space containing an air layer (i.e., an air gap).

A data storage pattern DSP may be provided on the landing pad LP. A plurality of data storage patterns DSP may be provided. The plurality of data storage patterns DSP may be spaced apart from each other in the first and second directions D1 and D2. Each of the data storage patterns DSP may be connected to a corresponding edge portion EA through a corresponding landing pad LP and a corresponding storage node contact BC.

The data storage pattern DSP may be, for example, a capacitor including a lower electrode, a dielectric layer, and an upper electrode. In this case, the semiconductor memory device may be dynamic random access memory (DRAM). As another example, the data storage pattern DSP may include a magnetic tunnel junction pattern. In this case, the semiconductor memory device may be magnetic random access memory (MRAM). As another example, the data storage pattern DSP may include a phase change material or a variable resistance material. In this case, the semiconductor memory device may be phase-change random access memory (PRAM) or resistive random access memory (ReRAM). However, example embodiments are not limited thereto, and the data storage pattern DSP may include various structures and/or materials capable of storing data.

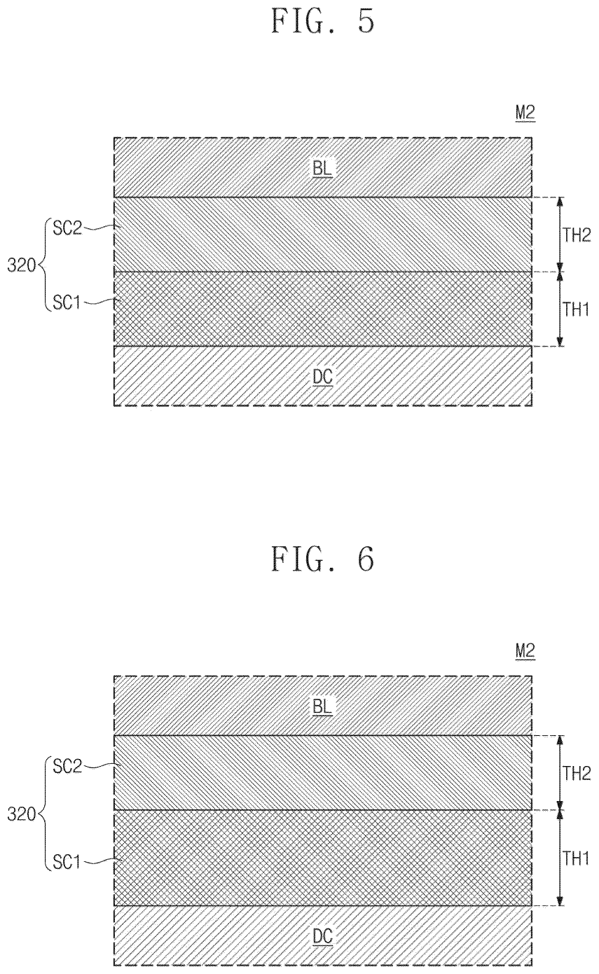

FIG. 5 is a view illustrating a semiconductor device according to example embodiments, and is an enlarged view corresponding to region ‘M2’ in FIG. 4.

Referring to FIG. 5, first and second silicide layers SC1 and SC2 may be interposed between the bit line BL and the bit line contact DC. The first silicide layer SC1 may have a first thickness TH1 in the third direction D3 perpendicular to the substrate 100, and the second silicide layer SC2 may have a second thickness TH2 in the third direction D3. The first thickness TH1 and the second thickness TH2 may be substantially the same. The sum of the first thickness TH1 and the second thickness TH2 may be greater than 0 nm and less than or equal to 5 nm.

As an example, a ratio of silicon (Si) to a metal element (e.g., Ti, Mo, W, Cu, Al, Ta, Ru, Ir, Co, Pt, Au, Ag etc.) for each of the first silicide layer SC1 and the second silicide layer SC2 may be 0.5 to 3.

The first silicide layer SC1 may have a first nitrogen concentration, and the second silicide layer SC2 may have a second nitrogen concentration. The first nitrogen concentration may be defined as an elemental ratio of nitrogen (N) in the first silicide layer SC1, and the second nitrogen concentration may be defined as an elemental ratio of nitrogen (N) in the second silicide layer SC2. The second nitrogen concentration of the second silicide layer SC2 may be greater than the first nitrogen concentration of the first silicide layer SC1.

The first and second silicide layers SC1 and SC2 may be formed through a deposition process and a heat treatment process. For example, the deposition process may be a physical vapor deposition (PVD) process or a physical vapor deposition (PVD) sputtering process. As an example, in a PVD process, nitrogen gas (N₂) may be used. During the deposition process, a flow rate of nitrogen gas (N₂) may be adjusted to independently control the first nitrogen concentration in the first silicide layer SC1 and the second nitrogen concentration in the second silicide layer SC2.

For example, a nitrogen plasma treatment process may be used to control the second nitrogen concentration. The nitrogen plasma treatment process may initially control the first nitrogen concentration to be greater than 0 at % and less than or equal to 32 at %. The nitrogen plasma treatment process may increase the second nitrogen concentration of the second silicide layer SC2 to 44 at % or more. That is, the nitrogen concentration in the first silicide layer SC1 may be initially controlled to a relatively low level, and the nitrogen concentration in the second silicide layer SC2 may be increased through the nitrogen plasma treatment process. For example, the nitrogen concentration of the second silicide layer SC2 may be increased from 32 at % or less (i.e., for the first silicide layer SC1) to 44 at % to 70 at % i.e., for the second silicide layer SC2) through a nitrogen plasma treatment process. As another example, the nitrogen concentration of the second silicide layer SC2 may be increased from 44 at % to greater than 44 at % and less than or equal to 70 at % through a nitrogen plasma treatment process.

In some example embodiments, the first nitrogen concentration may be greater than 0 at % and less than or equal to 32 at %, and the second nitrogen concentration may be greater than or equal to 44 at % and less than or equal to 70 at %. More preferably, the first nitrogen concentration may be greater than 0 at % and less than or equal to 24 at %.

For example, a contact resistance between the bit line BL and the bit line contact DC may be reduced when the first nitrogen concentration is 0 at % in a range where the first nitrogen concentration is greater than 0 at % and 32 at % or less, compared to when the first nitrogen concentration is greater than 32 at %.

The nitrogen concentration in the second silicide layer SC2 may affect a grain size and sheet resistance of the bit line BL. For example, the grain size of the bit line BL may be larger when the second nitrogen concentration is 44 at % or more and 70 at % or less compared to when the second nitrogen concentration is 0 at %. Therefore, the sheet resistance of the bit line BL may decrease when the second nitrogen concentration is 44 at % or more and 70 at % or less, thereby reducing signal transmission delay (RC delay). As an example, the bit line BL may include tungsten (W), and in this case, an array of (110)-oriented tungsten (W) crystals with low resistance characteristics inside the bit line BL may increase in a range where the second nitrogen concentration is 44 at % or more and 70 at % or less. As a result, the sheet resistance of the bit line BL may decrease when the second nitrogen concentration is 44 at % or more and 70 at % or less, thereby reducing signal transmission delay (RC delay).

That is, as the first nitrogen concentration of the first silicide layer SC1 has a numerical range of more than 0 at % and less than 32 at %, and the second nitrogen concentration of the second silicide layer SC2 has a numerical range of more than 44 at % and less than 70 at %, a contact resistance between the bit line BL and the bit line contact DC may be reduced, and at the same time, the sheet resistance of the bit line BL may be reduced. As a result, the overall resistance including the bit line BL, the ohmic pattern 320, and the bit line contact DC may be reduced, and the signal transmission delay (RC delay) may be reduced.

In another example, the first nitrogen concentration may be 0 at %, and the second nitrogen concentration may be 44 at % or more and 70 at % or less. In more detail, the first silicide layer SC1 may not contain nitrogen (N).

That is, the first silicide layer SC1 not containing nitrogen (N) may be disposed on the bit line contact DC, and the second nitrogen concentration of the second silicide layer SC2 may have a numeral rage of 44 at % or more and 70 at %.

FIG. 6 is a view illustrating a semiconductor device according to example embodiments, and is an enlarged view corresponding to region ‘M2’ in FIG. 4. Description will focus on differences from the semiconductor device according to the above-described example embodiment. For the sake of concise explanation, detailed descriptions of configurations that are identical/similar to those described above may be omitted.

Referring to FIG. 6, the first thickness TH1 of the first silicide layer SC1 may be greater than the second thickness TH2 of the second silicide layer SC2. A ratio of the second thickness TH2 to the first thickness TH1 may be 1 or less and 0.9 or more.

A resistance of the first silicide layer SC1 may be smaller than a resistance of the second silicide layer SC2. Accordingly, a resistance of the ohmic pattern 320 may be reduced in a range where the ratio of the second thickness TH2 to the first thickness TH1 is 1 or less.

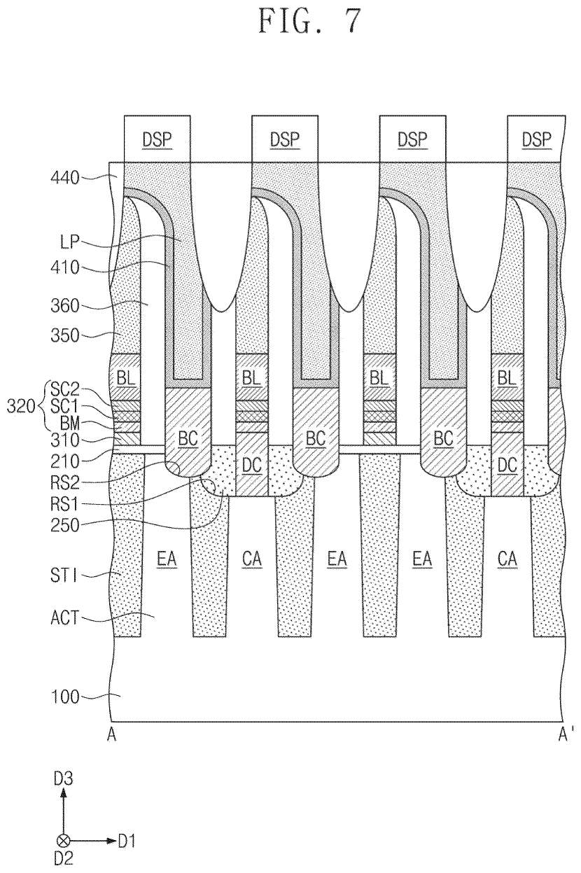

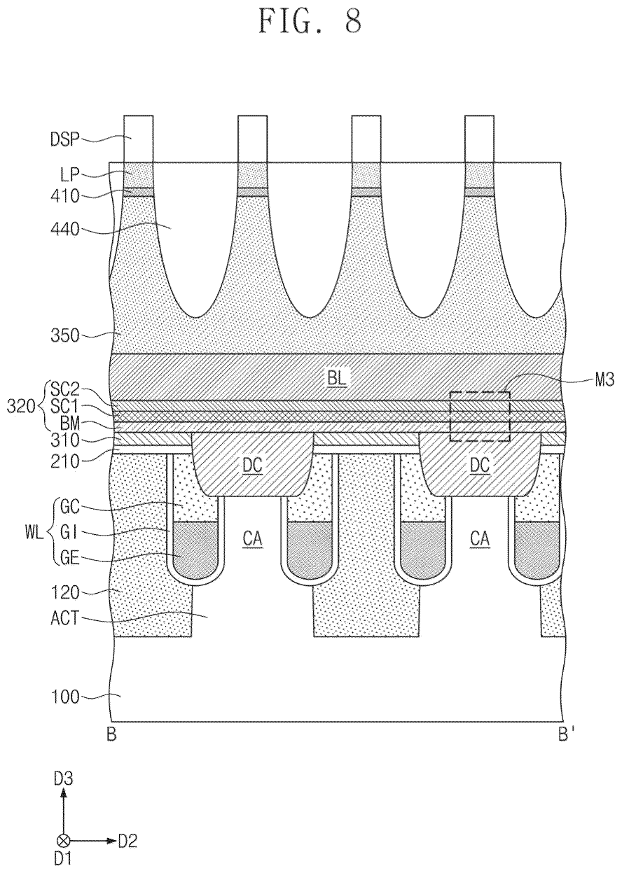

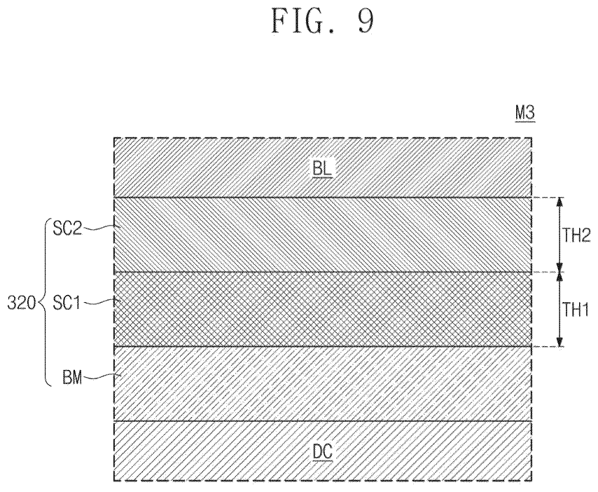

FIG. 7 is a view illustrating a semiconductor device according to example embodiments, and is a cross-sectional view corresponding to line A-A′ of FIG. 2. FIG. 8 is a view illustrating a semiconductor device according to example embodiments, and is a cross-sectional view corresponding to line B-B′ in FIG. 2. FIG. 9 is a view illustrating a semiconductor device according to example embodiments, and is an enlarged view corresponding to region ‘M3’ in FIG. 8. Description will focus on differences from the semiconductor device described above. For the sake of concise explanation, detailed descriptions of configurations that are identical/similar to those described above may be omitted.

Referring to FIGS. 7 to 9, an ohmic pattern 320 may include a first silicide layer SC1, a second silicide layer SC2, and a metal barrier layer BM.

The metal barrier layer BM may be interposed between the first silicide layer SC1 and the bit line contact DC and between the first silicide layer SC1 and the polysilicon pattern 310. The metal barrier layer BM may extend in the second direction D2 along the bit lines BL. A plurality of metal barrier layers BM may be provided. The plurality of metal barrier layers BM may be spaced apart from each other in the first direction D1. The metal barrier layer BM may include a metal material (e.g., Ti, Ta, Ni, Pt, Rh, Ir, Mo, Co, etc.). As an example, the metal barrier layer BM may include TiSiN.

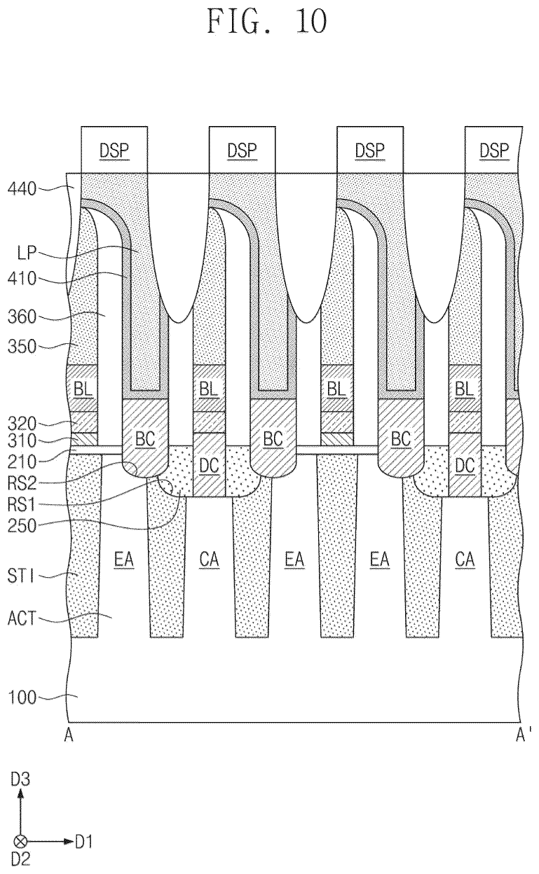

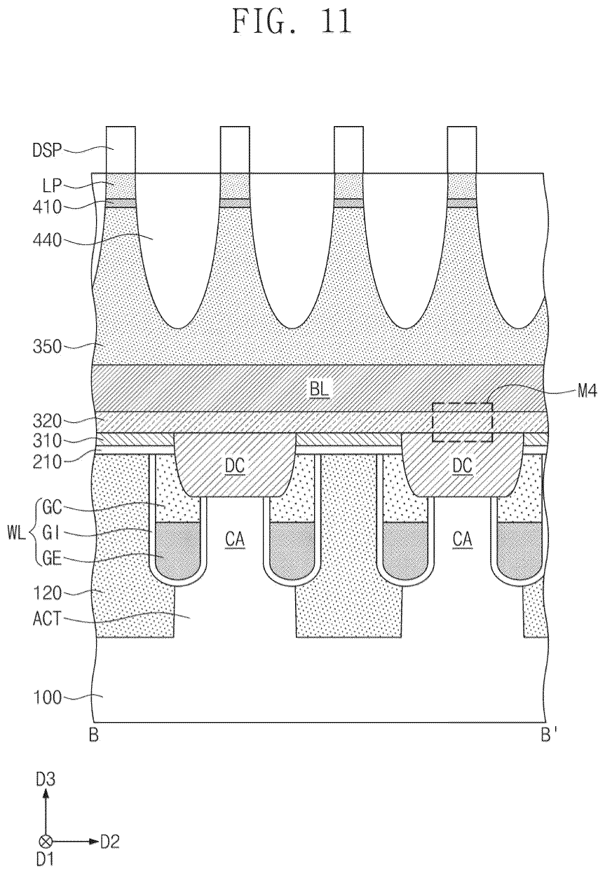

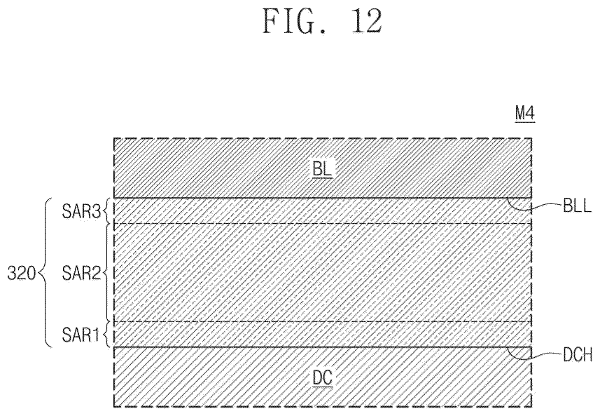

FIG. 10 is a view illustrating a semiconductor device according to example embodiments, and is a cross-sectional view corresponding to line A-A′ in FIG. 2. FIG. 11 is a view illustrating a semiconductor device according to example embodiments, and is a cross-sectional view corresponding to line B-B′ in FIG. 2. FIG. 12 is a view illustrating a semiconductor device according to example embodiments, and is an enlarged view corresponding to region ‘M4’ in FIG. 11. Description will focus on differences from the semiconductor device described above. For the sake of concise explanation, detailed descriptions of configurations that are identical/similar to those described above may be omitted.

Referring to FIGS. 10 to 12, an ohmic pattern 320 may include a metal element (e.g., Ti, Mo, W, Cu, Al, Ta, Ru, Ir, Co, Pt, Au, Ag, etc.), silicon (Si) and nitrogen (N). The ohmic pattern 320 may include a first region SAR1 in contact with the bit line contact upper surface DCH, a third region SAR3 in contact with the bit line lower surface BLL, and a second region SAR2 between the first region SAR1 and the third region SAR3. A thickness of the ohmic pattern 320 in the third direction D3 may be greater than 0 nm and less than or equal to 5 nm.

The first region SAR1 may have a first nitrogen concentration, the second region SAR2 may have a second nitrogen concentration, and the third region SAR3 may have a third nitrogen concentration. The first nitrogen concentration may be defined as an elemental ratio of nitrogen (N) in the first region SAR1, the second nitrogen concentration may be defined as an elemental ratio of nitrogen (N) in the second region SAR2, and the third nitrogen concentration may be defined as an elemental ratio of nitrogen (N) in the third region SAR3. In the ohmic pattern 320, the first region SAR1, the second region SAR2, and the third region SAR3 may be distinguished by the nitrogen concentration of each region.

The nitrogen concentration may increase from the first region SAR1 to the third region SAR3. That is, the second nitrogen concentration may be equal to or greater than the first nitrogen concentration, and the third nitrogen concentration may be greater than the second nitrogen concentration. In one example embodiment, the first nitrogen concentration may be greater than 0 at % and less than or equal to 32 at %, the third nitrogen concentration may be greater than or equal to 44 at % and less than or equal to 70 at %, and the second nitrogen concentration may have a numerical range of greater than or equal to the first nitrogen concentration and less than or equal to the third nitrogen concentration.

For example, a nitrogen plasma treatment process may be used to deposit the ohmic pattern 320.

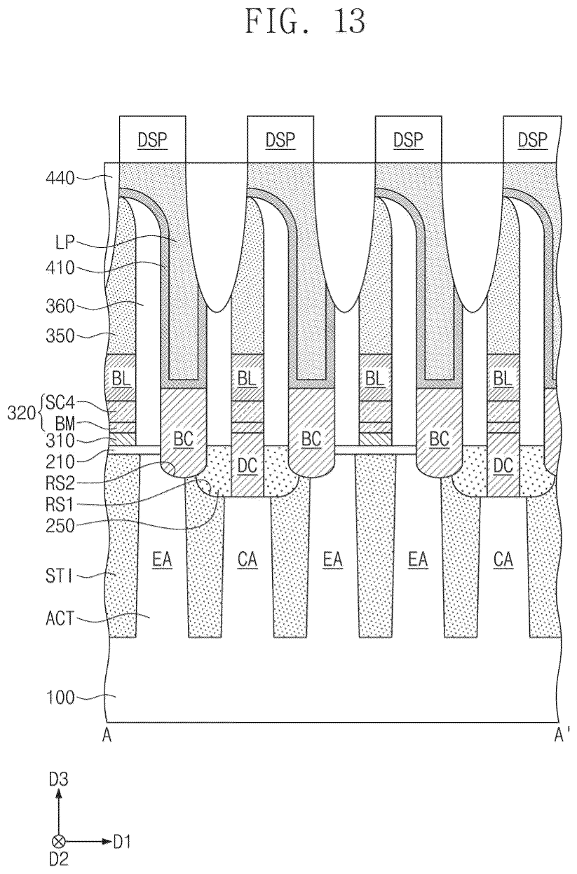

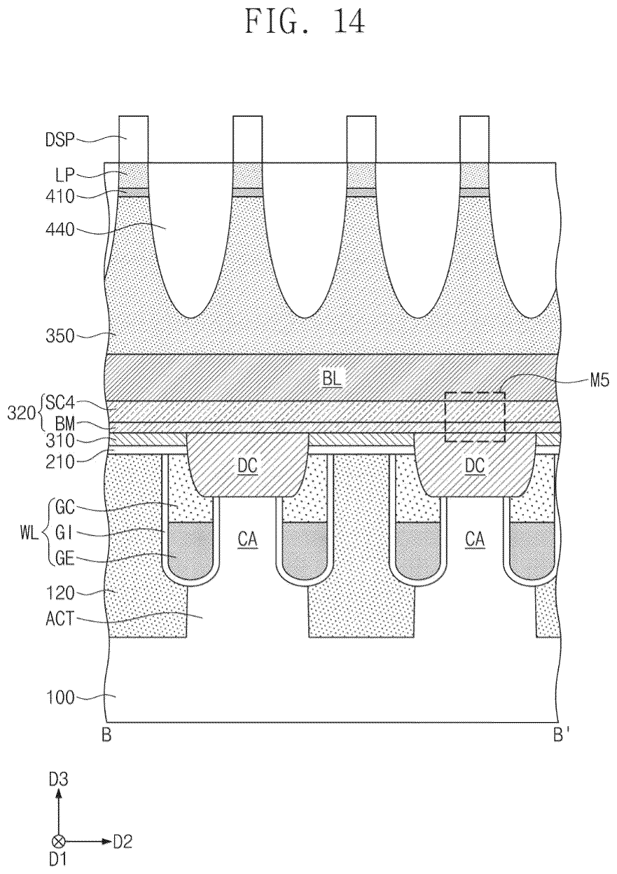

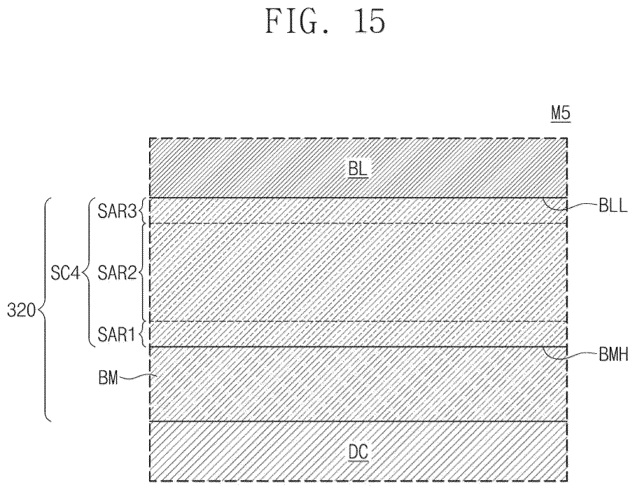

FIG. 13 is a view illustrating a semiconductor device according to example embodiments, and is a cross-sectional view corresponding to line A-A′ in FIG. 2. FIG. 14 is a view illustrating a semiconductor device according to example embodiments, and is a cross-sectional view corresponding to line B-B′ in FIG. 2. FIG. 15 is a view illustrating a semiconductor device according to example embodiments, and is an enlarged view corresponding to region ‘M5’ in FIG. 14. Description will focus on differences from the semiconductor device described above. For the sake of concise explanation, detailed descriptions of configurations that are identical/similar to those described above may be omitted.

Referring to FIGS. 13 to 15, an ohmic pattern 320 may include a fourth silicide layer SC4 and a metal barrier layer BM.

The fourth silicide layer SC4 may be interposed between the bit line BL and the metal barrier layer BM, and may include a metal element (e.g., Ti, Mo, W, Cu, Al, Ta, Ru, Ir, Co, Pt, Au, Ag, etc.), silicon (Si), and nitrogen (N). The fourth silicide layer SC4 includes a first region SAR1 in contact with the metal barrier layer upper surface BMH, a third region SAR3 in contact with the bit line lower surface BLL, and a second region SAR2 between the first region SAR1 and the third region SAR3. A thickness of the fourth silicide layer SC4 in the third direction D3 may be greater than 0 nm and less than or equal to 5 nm. In the fourth silicide layer SC4, the first region SAR1, the second region SAR2, and the third region SAR3 may be divided by the nitrogen concentration of each region.

The metal barrier layer BM may be interposed between the fourth silicide layer SC4 and the bit line contact DC and between the fourth silicide layer SC4 and the polysilicon pattern 310. The metal barrier layer BM may extend in the second direction D2 along the bit lines BL. A plurality of metal barrier layers BM may be provided. The plurality of metal barrier layers BM may be spaced apart from each other in the first direction D1. The metal barrier layer BM may include a metal material (e.g., Ti, Ta, Ni, Pt, Rh, Ir, Mo, Co, etc.).

The semiconductor device according to example embodiments may include one or more silicide layers between the bit line and the bit line contact, and provide different concentrations of nitrogen (N) contained in each silicide layer, thereby improving the reliability and electrical characteristics of the semiconductor device.

While aspects of example embodiments have been particularly shown and described, it will be understood that various changes in form and details may be made therein without departing from the spirit and scope of the following claims.

What is claimed is:

1. A semiconductor device comprising:
a substrate comprising an active pattern;
a bit line crossing the active pattern on the substrate;
a bit line contact provided between the bit line and the active pattern;
a first silicide layer provided between the bit line contact and the bit line; and
a second silicide layer provided between the first silicide layer and the bit line,
wherein each of the first silicide layer and the second silicide layer comprises a metal element, silicon (Si) and nitrogen (N), and
wherein the first silicide layer has a first nitrogen concentration, and the second silicide layer has a second nitrogen concentration that is greater than the first nitrogen concentration.

2. The semiconductor device of claim 1, wherein the first nitrogen concentration is greater than or equal to 0 at % and less than or equal to 32 at %.

3. The semiconductor device of claim 1, wherein the second nitrogen concentration is greater than or equal to 44 at % and less than or equal to 70 at %.

4. The semiconductor device of claim 3, wherein the first and second silicide layers are vertically stacked on the substrate, and
wherein the first nitrogen concentration is greater than 0 at % and less than or equal to 32 at %.

5. The semiconductor device of claim 1, wherein an element ratio of silicon (Si) to the metal element for each of the first silicide layer and the second silicide layer is greater than or equal to 0.5 and less than or equal to 3.

6. The semiconductor device of claim 1, further comprising a metal barrier layer provided between the bit line contact and the first silicide layer.

7. The semiconductor device of claim 6, wherein the bit line contact comprises polysilicon, and
wherein the metal barrier layer comprises any one or any combination of Ti, Ta, Ni, Pt, Rh, Ir, Mo, and Co.

8. The semiconductor device of claim 1, wherein the first silicide layer has a first thickness in a third direction perpendicular to the substrate,
wherein the second silicide layer has a second thickness in the third direction, and
wherein the first thickness is equal to or greater than the second thickness.

9. The semiconductor device of claim 8, wherein a ratio of the second thickness to the first thickness is less than or equal to 1 and greater than or equal to 0.9.

10. The semiconductor device of claim 8, wherein a sum of the first thickness and the second thickness is greater than 0 nm and less than or equal to 5 nm.

11. The semiconductor device of claim 1, wherein the bit line comprises the metal element, and
wherein the metal element comprises any one or any combination of W, Mo, and Ru.

12. A semiconductor device comprising:
a substrate comprising an active pattern;
a bit line crossing the active pattern on the substrate;
a bit line contact provided between the bit line and the active pattern; and
a silicide layer provided between the bit line contact and the bit line, the silicide layer comprising a first region adjacent to the bit line contact and a second region adjacent to the bit line,
wherein the silicide layer comprises a metal element, silicon (Si) and nitrogen (N), and
wherein a nitrogen concentration of the silicide layer increases from along a direction perpendicular to an upper surface of the substrate.

13. The semiconductor device of claim 12, wherein a nitrogen concentration in the second region is greater than or equal to 44 at % and less than or equal to 70 at %.

14. The semiconductor device of claim 13, wherein a nitrogen concentration in the first region is greater than 0 at % and less than or equal to 32 at %.

15. The semiconductor device of claim 12, further comprising a metal barrier layer provided between the bit line contact and the silicide layer.

16. The semiconductor device of claim 15, wherein the metal barrier layer comprises any one or any combination of Ti, Ta, Ni, Pt, Rh, Ir, Mo, and Co.

17. The semiconductor device of claim 12, wherein the bit line comprises the metal element, and
wherein the metal element comprises any one or any combination of W, Mo, and Ru.

18. A semiconductor device comprising:
a device isolation pattern defining active patterns on a substrate;
word lines crossing the active patterns on the substrate;
bit lines crossing the active patterns and intersecting the word lines;
a bit line contact provided between a central portion of an active pattern of the active patterns and a bit line of the bit lines;
a first silicide layer provided between the bit line contact and the bit line;
a second silicide layer provided between the first silicide layer and the bit line;
a storage node contact provided on the active patterns on both sides of the bit line;
a landing pad on the storage node contact; and
a data storage pattern on the landing pad,
wherein each of the first silicide layer and the second silicide layer comprises a metal element, silicon (Si) and nitrogen (N), and
wherein the first silicide layer has a first nitrogen concentration and the second silicide layer has a second nitrogen concentration that is greater than the first nitrogen concentration.

19. The semiconductor device of claim 18, wherein the first nitrogen concentration is greater than 0 at % and less than or equal to 32 at %, and
wherein the second nitrogen concentration is greater than or equal to 44 at % and less than or equal to 70 at %.

20. The semiconductor device of claim 18, wherein a first thickness between upper and lower surfaces of the first silicide layer is greater than a second thickness between upper and lower surfaces of the second silicide layer.
